(19) United States
(12) Patent Application Publication
(10) Pub. No.: US 2005/0285602 A1
(43) Pub. Date: Dec. 29, 2005

(54) Use of magnetic noise compensation in localization of defect in flat plate structure

(76) Inventor: John E. Field, Dorrington, CA (US)

Correspondence Address: John E. Field, 678 Boards Crossing Road, Box 4076, Dorrington, CA, 95223, US

(21) Appl. No.: 11/145,059

(22) Filed: Jun. 3, 2005

Related U.S. Application Data
(60) Provisional application No. 60/577,482, filed on Jun. 7, 2004.

(51) Int. Cl. G09G 5/00; G01R 31/28

(52) U.S. Cl. 324/529

(57) ABSTRACT

The noise associated with induced Emf in a flat plate structure is significantly reduced by using a compensation coil or other magnetic detector. Additional noise reduction is provided by using a second magnetic detector, preferably another coil with many turns, combined with analog or digital signal processing. The lower noise level allows for greater sensitivity in the measurement of defects or electrical properties in flat panel displays (FPD).

### CROSS-REFERENCE TO RELATED APPLICATIONS

U.S. Pat. No. 6,545,500 Field, Use of Localized Temperature Change in Determining the Location and Character of Defects in flat-Panel displays

U.S. Pat. No. 6,118,279 Field, Magnetic Detection of Short Circuit in Plate Structure

U.S. Pat. No. 6,593,156 Nikawa, Non-destructive inspection method

U.S. Pat. No. 6,610,918 Nikawa, Device and method for nondestructive inspection on semiconductor device

USPTO Provisional Application # 60577482, Field, Use of Magnetic Noise Compensation in Localization of Defect in Flat Plate Structure

### BACKGROUND

This invention relates to the use of compensating magnetic measurements to improve the determination of the location and character of defects and electrical properties in or on flat panel displays such as, but not limited to, those as used in laptop computers.

A flat panel display includes a sandwich of rows and columns separated by an insulating or semi-insulating material. Because there are typically thousands of rows and columns, there are then literally millions of opportunities for the rows and the columns to become shorted together due to microscopic defects that occur during manufacturing. Additionally, many other defect types are possible—broken row or column traces, undesired thin film properties, etc. Because there is a great deal of cost in the processing of flat panel display (FPD) plates, for cost-effective manufacturing, it is necessary to identify these defects and repair or discard the panels early in the manufacturing process. There is a large collection of methods for the identification of these defects. See for example Field, “Use of Localized Temperature Change in the Detection of Defects in Flat Plate Structure.”

Typically, the test is performed on a testing machine that is equipped with motion means to move test equipment relative to the FPD under test. Usually, the FPD under test is affixed to a wafer chuck that holds it at a known position or positions during the test. The wafer chuck may be made of many different materials such as aluminum, glass, or steel, and its design and fabrication may affect the results of sensitive electronic measurements as well.

The subject of the present invention is an improvement to a class of methods in which the presence or non-presence of a defect is sensed by measuring electrical signals between the rows and the columns. More specifically, there are methods in which all or many of the rows and columns may be electrically connected using one, two, or more electrical busbars patterned on the plate.

In one method, described by Field in U.S. Pat. No. 6,545,500, a laser is scanned around the perimeter of a flat panel display to generate localized heating. This heating results in a thermoelectric or thermoresistive electric signal that appears between the row and column busbars of the display. This electric signal is measured by a voltmeter or an ammeter (hereafter referred to as volt/ammeter).

It will be appreciated that this present invention would apply to other methods that generated an electrical signal within the flat panel display as well.

In many, if not all of these methods, there is a noise process present due to the fact that in the environment, there is always a background fluctuating magnetic field due to electrical currents in the vicinity. The source of these electrical currents may be other electronic equipment nearby, natural, as in the case of lightning, the mechanical motion of magnetic objects, even quantum fluctuations, or many other natural and man-made sources. The noise is due to the fact that these magnetic fluctuations penetrate the flat panel and generate an induced Emf in the electrical circuit formed by the FPD. The presence of this noise may set the limit on the sensitivity of these methods. It is clear that in a complex piece of equipment such as a flat panel display tester, there may be many moving parts with magnetic properties, such as the wafer chuck or a loading robot, as well as significant amounts of electronic equipment that all generates background noise as a consequence of its operation. Therefore, a means to reduce or eliminate this noise would be a significant advancement of the art.

The present invention discloses a method to sharply reduce the magnitude of this noise as reported by the detection apparatus by compensating for the induced Emf in the plate. Because the flat panel display has distributed circuitry across the active area of the display, it is generally not the case that the total induced Emf is equal to the time derivative of the flux penetrating the active area. The present invention discloses a method by which coils can be employed to generate Emfs approximately equal and opposite to those generated in the FPD.

It is important to understand that the present invention is used to compensate for an undesirable environmental effect—namely that of varying background magnetic fields. It is not using magnetic fields to effect a measurement of defects on the flat panel display directly. Furthermore, measurements are made of currents induced in the device under test rather than of magnetic fields generated by the device. Therefore, it is distinguished from methods which drive currents in the device in order to induce magnetic fields which are then measured, a few of which are described below.

In the separate art of semiconductor integrated circuit testing, there are methods disclosed in which the magnetic field generated by electrical currents driven in the integrated circuit is of interest for the test. See, for example, U.S. Pat. Nos. 6,593,156 and 6,610,918 due to Nikawa, incorporated herein by reference. In this case, the magnetic field is measured by a very small and highly sensitive magnetic detector, such as a SQUID, and the detector typically moves with respect to the integrated circuit under test. The diagnostic measurement being made is a measurement of the magnetic field induced by flowing currents. Direct electrical contact with the wafer is usually not made except to supply power, and in that case, highly sensitive measurement of the voltage or current flow is not made. The cause and effect relationship is reversed from that of the present invention, and the effect is deliberately induced rather than being an undesired noise source to be suppressed.

Similarly, magnetic microscopy has been used in the detection of defects on flat panel displays, as in U.S. Pat. No. 6,118,279 due to Field. As in the integrated circuit case decribed above, flowing currents induce magnetic fields which are detected, albeit in a different arrangement. In all the configurations described, however, spurious background magnetic fields would be directly detected and not any residual magnetic fields due to induced currents in the device under test.

### BRIEF SUMMARY OF THE INVENTION

For the purposes of the present discussion, magnetic detector will include a coil, a hall-effect device, a magnetoresistive device, a SQUID (Superconducting Quantum Interference Device) or other devices used for the detection of small magnetic fields.

For the purposes of the present discussion, a flat panel display (FPD) will include the incomplete assembly of a flat panel display which includes the electronic switching elements required to produce an image on the assembled screen. For example, in an AMLCD device, this includes the TFT (thin-film transistor array). For an FED device, it includes the plate containing the electron emitters. For an OLED device, it would include the plate which may or may not have the light emitting substance deposited on it yet.

For the purposes of this discussion, the total induced Emf or total Emf is the circuit voltage resulting from the collection of all the Emfs generated by all the wiring circuits on the flat panel display (FPD). This circuit voltage is measured at the contact points to the plate.

It is the case that there are small varying magnetic fields in the environment. These fields are due to many factors—electronic equipment, the motion of magnetic objects, quantum mechanical fluctuations, etc. Some of these fluctuations are periodic, such as the 60 Hz line noise from electrical power, while others are spurious and non-stationary, as for example those due to a solenoid switching or an electric motor starting. Periodic noise is less of a problem because much, although not all, of it may be subtracted out by measuring the baseline level of the periodic signal and then subtracting an equivalent periodic signal from the signal of interest. Of course, noise is introduced in the subtraction process. Non-stationary sources pose a much more serious problem, however. In this case, the noise source may appear and/or disappear at any instant without warning and may have arbitrary magnitude. Since the purpose of the measurement is often to find defects of unknown type and location, these spurious signals can lead to ambiguous or incorrect determination of defects or other measurements. Furthermore, they may reduce the fidelity with which measurements may be made. It is a purpose of the present invention to sharply reduce or even eliminate this noise effect, and as such the present invention will be appreciated as a significant advancement of the art.

For the purposes of the present discussion, a compensation coil or a magnetic pickup coil will be a magnetic detector composed of one or more turns of wire placed in proximity to the flat panel display during test, or patterned onto the substrate of the flat panel display itself. The shape of the coil may be varied in accordance with methods disclosed in the present invention or other ways that would be apparent to a person ordinarily skilled in the art of electromagnetic design. The voltage or current measured across the coil is indicative of the time derivative of the magnetic flux penetrating the coil.

In one embodiment of the present invention, a compensating coil is wound so as to capture a roughly equal in magnitude, but opposite in sign quantity of magnetic flux from the environmental noise. This coil is then connected in series with the busbar connections on the FPD so that the net induced Emf of the series combination of the compensating coil and the FPD is approximately zero independent of the magnitude of the fluctuating background magnetic flux level.

In yet another embodiment of the present invention, several compensating coils are wound and combined with a set of electrical switches or relays so that the amount of magnetic flux captured from the background fluctuations can be adjusted under computer or manual control. The adjustment can be made so as to compensate for the induced Emf in the FPD.

In yet another embodiment of the present invention, the compensating coils or measurement coils are not attached directly to the FPD, but are attached to electronic means which then permit measurement of the background noise signals which may then be subtracted from the noise in the FPD either by analog electronic, digital electronics, or computer software means.

In yet another embodiment of the present invention, a first compensation coil is wound and attached in series with the FPD so as to reduce or eliminate the background noise, and an additional second or more compensation coils are wound and attached to electronic means which then permit measurement of the background noise signals which may then be used to help compensate for or detect the presence of residual noise which may not have been eliminated by the first said compensation coil.

In yet another embodiment of the present invention, one ore more compensation coils are attached to electronic means that measure the background noise and the presence or absence of noise are used to infer a signal input from the FPD which may be spurious due to a sudden noise input.

In yet another embodiment of the present invention, a magnetic detector, such as a hall-effect device, is used to measure the background noise level and the signal from this magnetic detector is measured by electronic means which then permits the noise to be subtracted out by further analog electronic, digital electronic, or computer software means.

In yet another embodiment of the present invention, several magnetic detectors, such as hall-effect devices, are used to measure the background noise level and the signal from these detectors is measured by electronic means which then permits the noise to be subtracted out by further analog electronic, digital electronic, or computer software means.

In yet another embodiment of the present invention, a collection of magnetic detectors of any sort, such as coils, hall effect devices, magnetoresistance devices, or other magnetic detectors, are combined so as to permit the estimation of the background noise that would be generated in an FPD in the proximity.

In yet another embodiment of the present invention, the magnetic detectors are fabricated directly on the plate structure of the flat panel display. For example, a coil could be patterned around the active area of the display and connected in the opposite sense from the induced Emf for a particular background noise fluctuation.

In yet another embodiment of the present invention, the information recovered from the measurement coils, compensation coils, or magnetic detectors is used to invalidate the particular signals as being spurious and due to background noise and not due to defects or electrical characteristics of the flat panel display itself.

In yet another embodiment of the present invention, the information recovered from the measurement coils, compensation coils, or magnetic detectors is used to adjust the significance of the information in the received signals from the flat panel display to be of greater or lesser significance due to the presence of background noise.

In yet another embodiment of the present invention, the compensation coil is wound in a shape and configuration so as to effect a cancellation of spatially varying background fields penetrating the FPD. A method of designing such coils is disclosed.

### BRIEF DESCRIPTION OF THE DRAWINGS

FIG. 1 depicts the typical configuration for a flat panel display under test with the rows(122) and columns(112) crossing each other in the active area(90) of the display and connected by row(121) and column(111) busbars. Electrical signals generated by the test as well as signals from the background noise are measured in the volt/ammeter electronics(100). Background noise also generates an Emf in coil(141) which is measured by coil pickup electronics(103).

FIG. 2 depicts another preferred embodiment of the present invention. A compensation coil(141) is connected in reverse polarity to the sensing volt/ammeter(100) so as to effect a cancellation of the induced Emf noise measured by the volt ammeter(100).

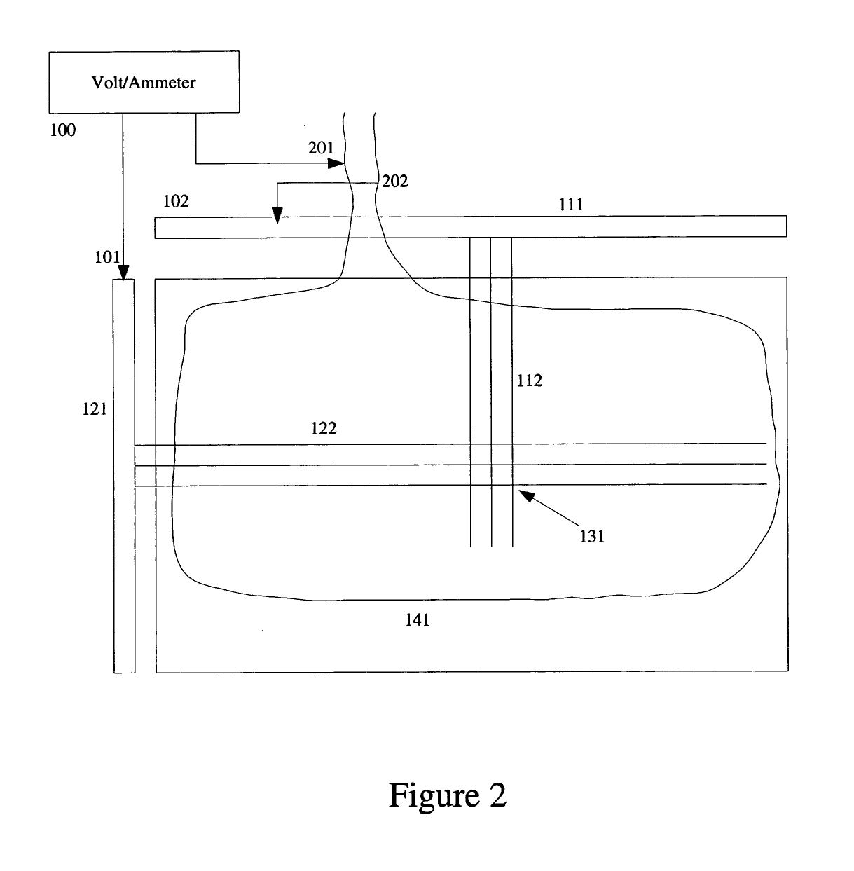

FIG. 3 depicts yet another preferred embodiment of the present invention. It shows a compensation coil(141) as well as a magnetic pickup coil(341). The compensation coil(141) is connected in reverse polarity to effect a cancellation of the induced Emf. The magnetic pickup coil(141) allows for correction adjustment for small amounts of noise that are present due to imperfect cancellation by the compensation coil(141).

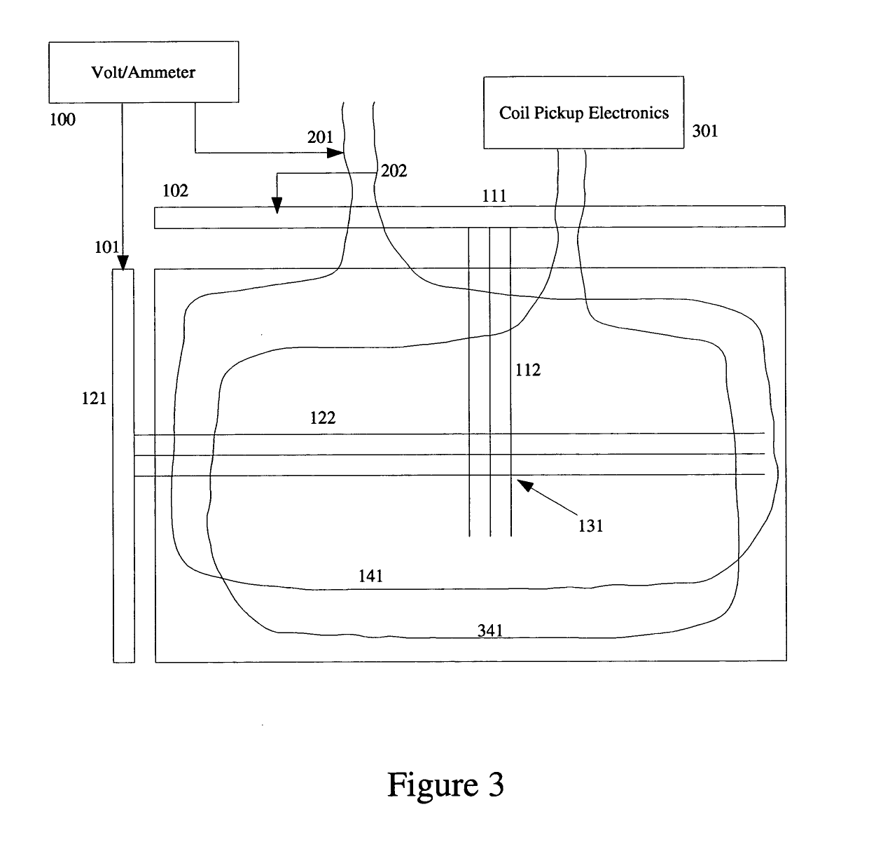

FIG. 4 depicts yet another embodiment of the present invention. In this case, the signal from the magnetic pickup coil(341) is combined in subsequent signal processing and combining electronics(401) to effect a reduced overall noise level.

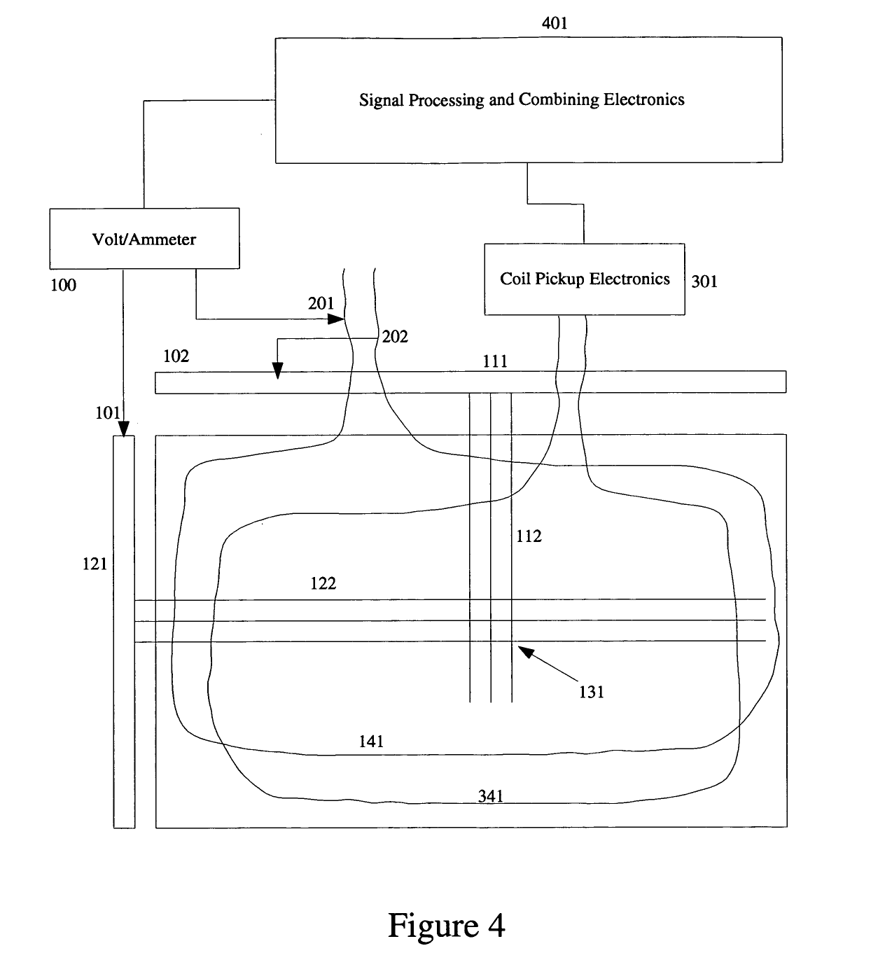

FIG. 5 depicts yet another embodiment of the present invention. In this case, a magnetic detector(502), such as a hall probe, is used instead of the magnetic detection coil(341) used in FIG. 4 to achieve the same result.

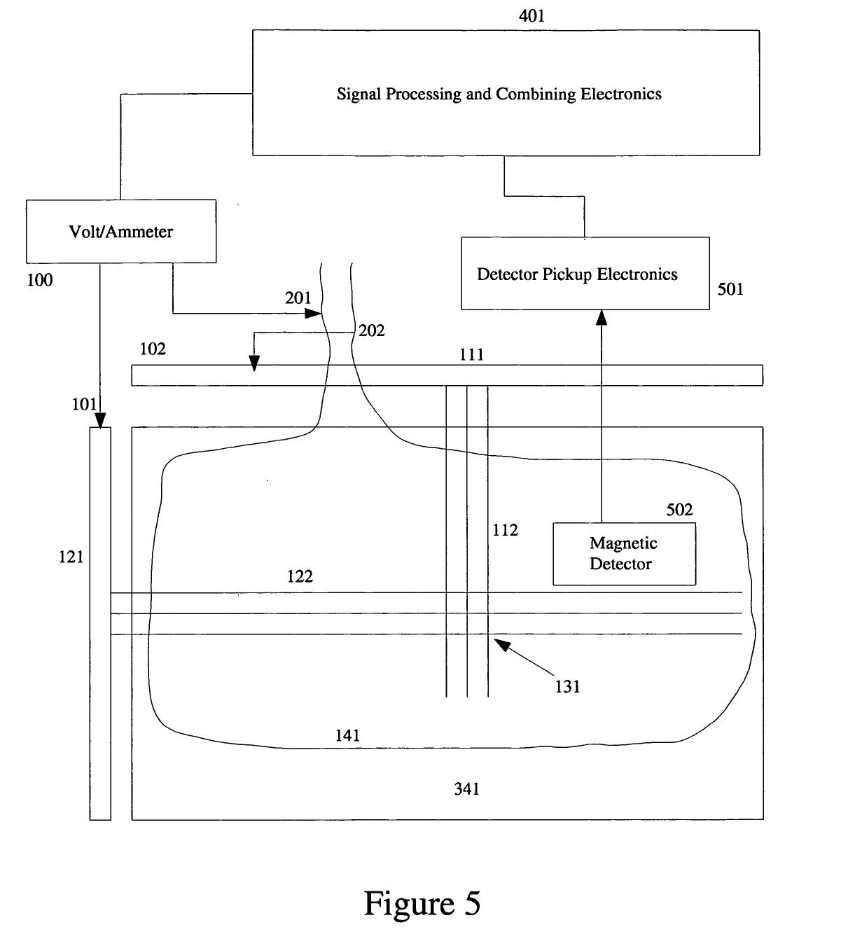

FIG. 6 shows a typical received signal without a compensation coil present.

FIG. 7 shows a typical received signal in the presence of a compensation coil wired to cancel the noise from background magnetic fluctuations.

FIG. 8 shows a calculated field distribution for magnetic field penetrating a solid aluminum wafer chuck.

FIG. 9 shows an approximate depiction of a compensation coil designed to eliminate first order spatial variations in the magnetic background field.

FIG. 10 shows an approximate depiction of a compensation coil designed to eliminate first and second order spatial variations in the magnetic background field.

### DETAILED DESCRIPTION OF THE INVENTION

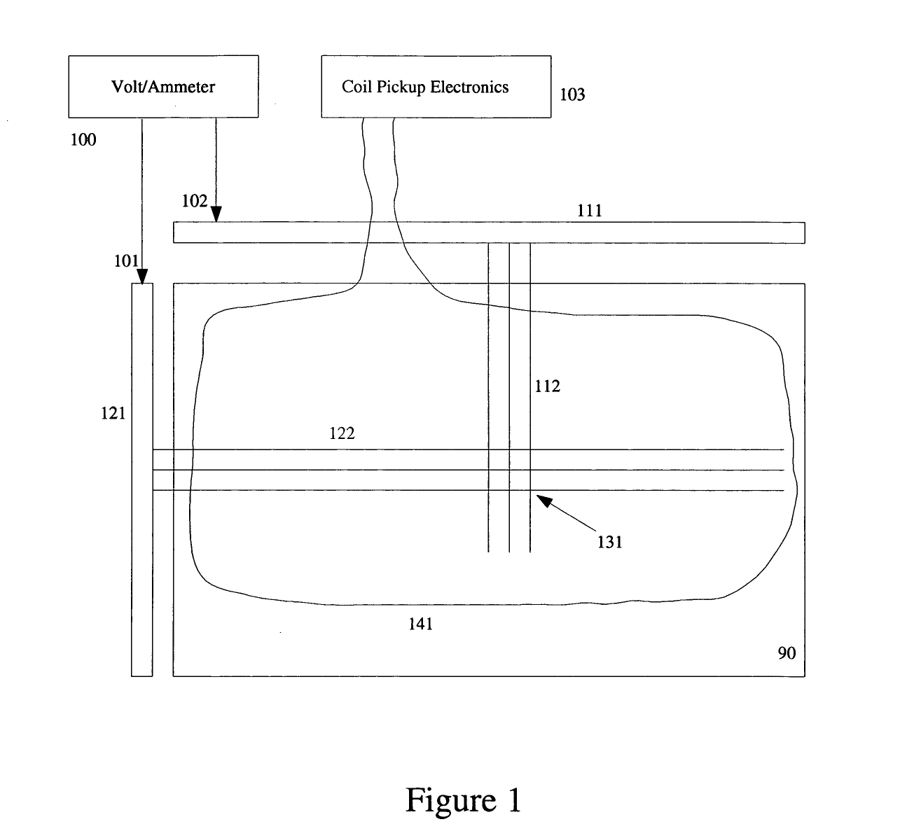

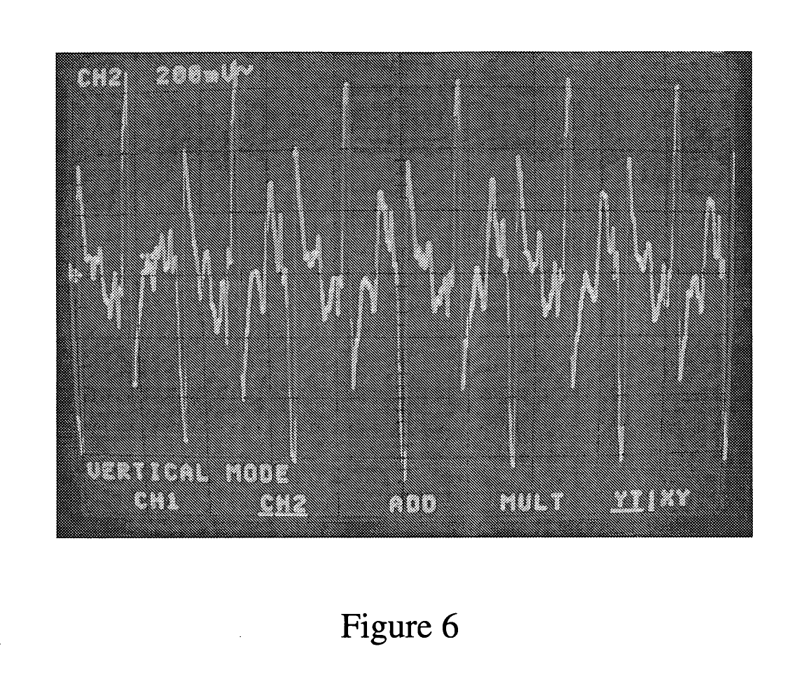

A flat panel display(FPD) includes a collection of rows(122) and columns(112) as shown in FIG. 1. There are typically one or more connection busbars to the rows(121) and columns(111). Combined with the switching elements which may be present at each pixel(131), it is actually a complex electronic circuit. The presence of background magnetic fluctuations generates small induced Emfs distributed on the FPD. FIG. 6 shows a typical measured signal oscilloscope trace for Emfs generated by the background magnetic fields.

The purpose of the present invention is to reduce or eliminate this noise source and thereby improve sensitivity and selectivity of defect detection schemes based on measurement of electrical signals on the FPD plate.

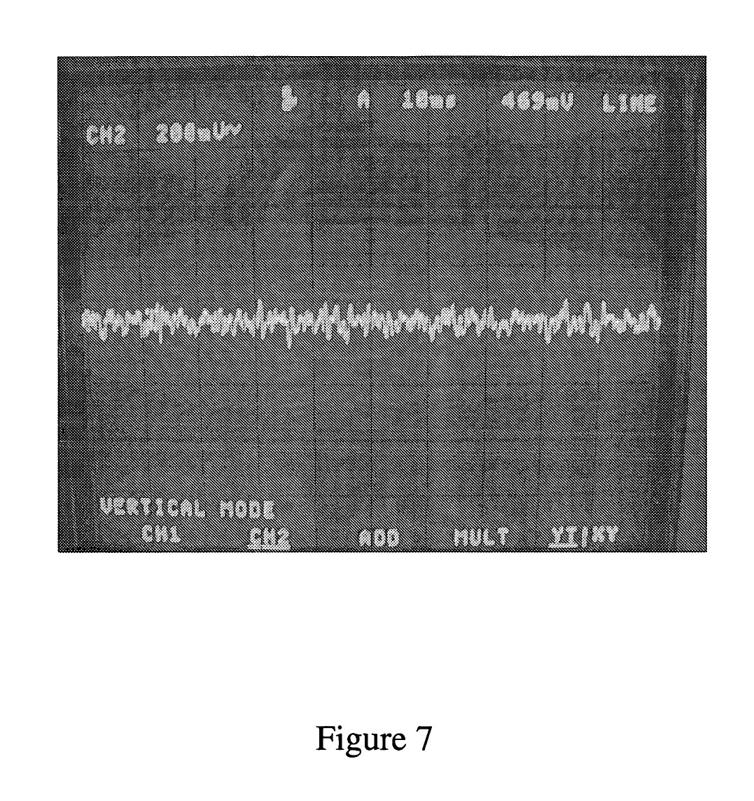

A compensation coil is wound so as to generate a counteracting Emf of equal magnitude to that generated in the FPD plate and then wired in series with the plate to remove the noise by methods disclosed below. FIG. 7 shows a typical trace for background Emfs generated with a matching compensation coil wired in series. Note that the noise is essentially eliminated.

To the extent that a measurement of electrical response is made, the noise from the background fluctuations includes a combined electronic circuit response to excitation from the complete collection of all these induced Emfs. As a consequence, it is not the case that the expected Emf is equal to the time derivative of the total magnetic flux penetrating the plate as might be expected on first glance. This collected circuit response is referred to as the total induced Emf.

In the case of low frequencies, low resistance traces, and a rectangular FPD with row(121) and column(111) busbars whose electrical properties are dominated by the capacitance between the rows(122) and the columns(112), with a time varying but spatially constant magnetic field it is possible to calculate the induced response in closed form. The result of this calculation is that the induced Emf at the volt/ammeter(100) is approximately ¼ of the time derivative of the penetrating flux. Mathematically,

$$Emf = \frac{1}{4} \frac{ⅆ Φ}{ⅆ t} ,$$

where Φ=Sum of flux penetrating FPD.

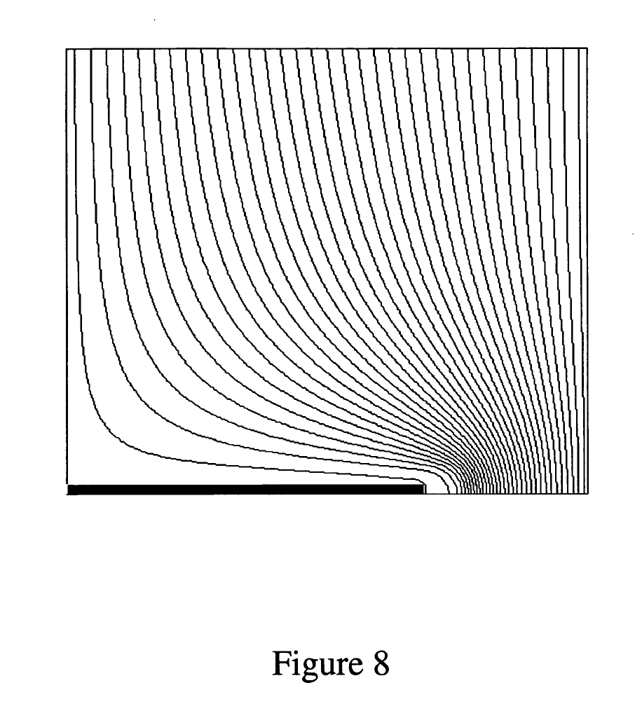

In the general case, the magnitude of the induced Emf will vary. For example, the magnetic field may not be constant across the entire area enclosed by the electric circuit of the flat panel display. This may be due to the natural variation of the background field, or, it may be due induced fields or currents in parts of the testing apparatus itself. A common example of this effect is the induced eddy currents in the wafer chuck which the FPD is normally situated on. These eddy currents tend to perturb the normal path of the magnetic field and may result in spatially varying fields across the FPD. FIG. 8 shows a calculated field distribution for a 1 inch thick round wafer chuck made of aluminum and a 200 Hz varying magnetic field. (The centerline of the wafer chuck is on the left vertical axis.) It is frequently the case, thus, that these perturbations are predictable and therefore the net induced Emf in the FPD can be calculated mathematically, or even if not, it may be measured empirically.

In theory, it would be possible to use a highly conductive or even superconducting wafer chuck so as to prevent the background magnetic field from penetrating the FPD. As a practical matter, at the low frequencies involved—hundreds or thousands of hertz—the skin depth of the best known conductors is still millimeters to centimeters and therefore considerable magnetic penetration will take place even with a very thick wafer chuck. While a superconducting wafer chuck could, in principle, solve the problem, the cryogenic nature of presently available superconductors makes such a wafer chuck impractical.

It is important to note that these induced magnetic field patterns, as well as the FPD circuit response, will in general be functions of the frequency of the magnetic fluctuations. Therefore, the measurements may need to be done at a collection of frequencies. Furthermore, nonlinear materials in the FPD or in the neighborhood of the FPD may result in nonlinear response. In this case, it may also be necessary to measure the transient response of the FPD to expected typical transient events in the typical background magnetic field.

The design of particular compensation coils can be effected so as to result in a first, second, or even higher order cancellation of the induced Emfs in the FPD as a function of spatial variations of the magnetic background fields. For example, in the case of low frequency, and a purely capacitive FPD plate, spatially constant magnetic field, it would be possible to wind a coil with an area-turns product of approximately ¼ of the FPD area and connect it in series but opposite in orientation, so as to effect a first-order cancellation of the total induced Emf. Note that the coil may have more than one turn if the area is reduced accordingly. To the extent that the background fields are not constant in space, different shape or even multiple separated coils with several loop areas could be used to effect higher order cancellations. Note that for calculational purposes, it is frequently desirable to approximate the active area of the FPD by two layers (rows and columns) of anisotropically conducting media coupled by an area admittance associated with the interlayer capacitance and conductance through the circuit elements.

In addition to the first said compensating coil, it is possible to use an additional magnetic detector or detectors to measure the field in time and space. This information can then be used in further analog electronics, digital electronics, or computer software means so as to subtract out residual noise which was not completely eliminated by the first said compensation coil.

The advantage of such an arrangement will be apparent to a person with ordinary skill in the art of low noise electronics. As the primary coil reduces noise before measurement, it increases dynamic range, reduces harmonic distortion and intermodulation effects in the measurement process. It also helps to reduce quantum noise, if significant, as well as other types of electronic noise which may be present in the sensitive detection apparatus.

Because the magnetic fields may vary in space, it will be appreciated that it is desirable to effect the measurement of the background magnetic field, as with a coil, in as close proximity to the FPD under test as possible. Increased distance will lead to decreased correllation between the background magnetic fluctuations and the subtracted cancelation signal. This is true for both the compensation coil connected in series as well as for a measurement coil.

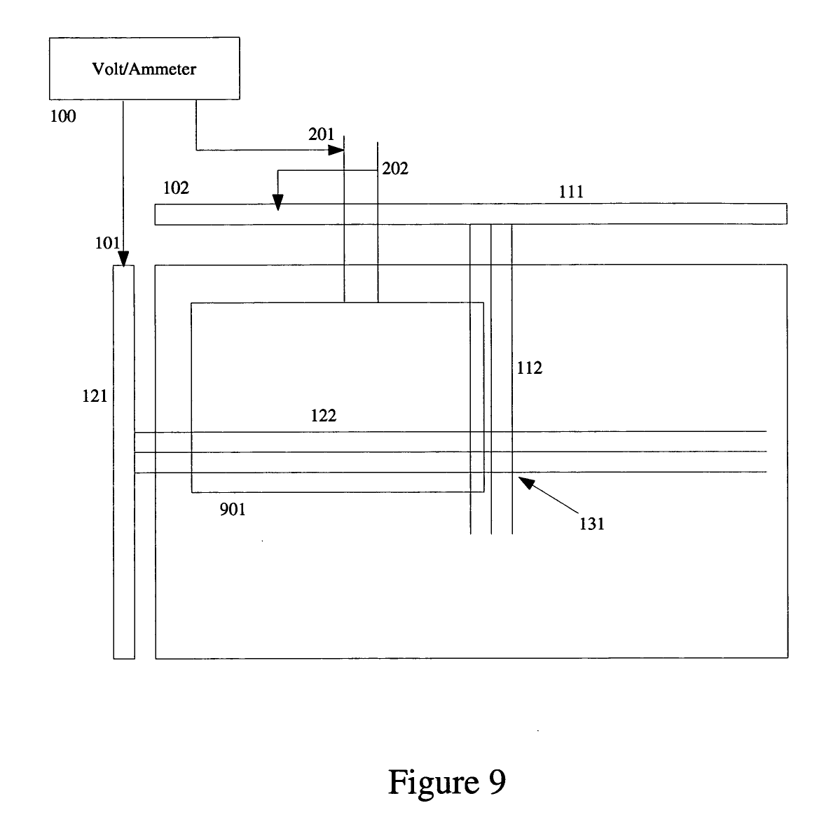

If we further assume that the background magnetic field varies linearly in space over the region of the plate, and we make the assumptions as above that the plate impedances are primarily determined by the capacitive couplings between the rows and the columns, it is possible to determine an optimal placement and size for the compensation coil to eliminate the effect of the spatially varying magnetic field (at least to first order). One particular solution of this problem is that the coil should have a height and width equal to one half of the height and width of the active area of the flat panel display, and that the coil center position should be ⅓ of the way across the columns and ⅓ of the way down the rows. This assumes that the row and column busbars are very close to the active area and the the loop will be closed by the measuring apparatus at the upper left corner of the display. FIG. 9 depicts what this special compensation coil(901) would approximately look like for this case.

Noise cancellations of higher order can be achieved by calculating the total induced Emf as a function of the coefficients in a Taylor series of the spatial dependence of the magnetic fields. By equating these coefficients to the calculated Emf generated by a carefully selected coil, it is possible to identify a size, shape, and position of a compensation coil that will eliminate the magnetic background noise to increasing order of approximation. There is a collection of solutions to this problem.

Mathematically speaking, a solution is to be found to the following problem in two dimensions for the cancellation of the first N order variations in space

$$\frac{{∮}_{FPD} ⅆ {A}^{′} {∮}_{{A}^{′}} ⅆ A {\sum }_{i = 0}^{N} {\sum }_{j = 0}^{i} {a}_{ij} {x}^{j} {y}^{i \cdot j}}{{∮}_{FPD} ⅆ A} = {∮}_{COIL} ⅆ A {\sum }_{i = 0}^{N} {\sum }_{j = 0}^{i} {a}_{ij} {x}^{j} {y}^{i \cdot j}$$

∀possible choices of αᵢⱼ, dA=dx dy,
N is the order number of cancellation,
FPD is the enclosed loop panel area, and
COIL is the enclosed coil turns x area

The surface integrals here are over the specified area and are thus each 2-dimensional sums—collectively forming a 4-dimensional integration in the numerator on the left. This equation assumes that the row and column busbars run along one side of the display (e.g. left and top) and are approximately coincident with the edge of the active area. The wiring in the active area is assumed to be uniform across the area and consist of orthogonal rows and columns. In the usual case, the FPD area of integration is rectangular. This equation includes the low-frequency capacitive approximation described above. If this approximation is not valid, it is necessary to replace this integral with a formal evaluation of the total induced Emf generated by the plate as conventionally computed in the art of electromagnetics and electronic circuit theory. For complex cases, it may not be possible (or at least not advantageous) to solve these equations in closed form and a suitable approximate solution can be found using electrical or electromagnetic equation solvers such as SPICE. Highly accurate solutions can be found by partitioning the flat panel display into many sub regions which can then be connected into a network and entered into the simulator for solution. By increasing the value of N, it is possible to use these procedures to compute the size and shape of more complex coils that can effect high order cancellations. It is not necessary that the coil be formed in a rectangular fashion, nor is it necessary that the coil consist of a single contiguous area. More than one solution is possible for a given background field distribution to achieve a given finite order of noise cancellation.

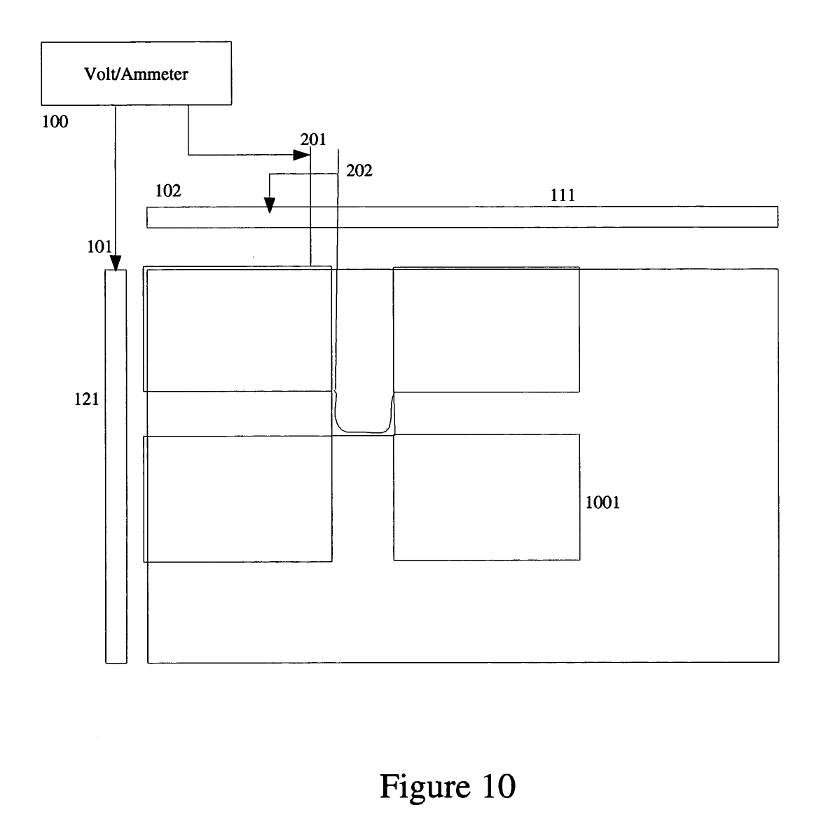

FIG. 10 shows an example of a compensation coil(1001) designed to eliminate constant, first, and second order spatial variations in the magnetic background field. The shape was calculated consistent with solution of the above integral equations. Just as for the linear case, the centroid of the pattern is about 33% down and right from the upper left corner. The four square coils are wound with a width and height of 25% of the width and height of the panel under test respectively. The squares are separated in width and height by a distance equivalent to approximately 20% of the width and height respectively of the panel under test. Again, the low frequency and capacitively dominated approximation has been used here. It will be appreciated that this approximation is only made for illustrative purposes. For a given panel configuration and/or if inductive and resistive effects are non-negligeable, it is a straightforward matter to solve the equations matching the induced Emf in the coil with the total induced Emf in the panel for arbitrary orders of spatial variation in the magnetic fields.

Furthermore, because the product configuration may vary, it will be apparent that another advantageous aspect of the present invention is that is would be possible using relays or other electronic or mechanical switches to reconfigure a multipart coil so as to effect a cancellation for varying sizes, shapes, or electronic configurations of flat panel display without physically modifying the coils themselves which are part of the apparatus. Even the connection orientation of sub-coils can be changed so as to effect improved cancellations in a custom way for particular products.

It will be appreciated that it is possible that many displays will be fabricated on a single FPD wafer. In this case, the size and shapes of the compensation coils can be calculated in the same way for the configuration to be tested. Indeed, it is possible to have a single compensation coil that would effect a partial cancellation for several displays or display configurations on the FPD. By using relays or other electronic switching means, it is possible to combine or select coils so as to minimize the noise observed from a particular one or ones of the FPDs on the wafer in this case.

It is possible to use any combination of compensation and measurement coils or detectors so as to effect the noise subtraction which is the subject of the present invention. Indeed, it would be possible to partially subtract the noise with the compensation coil and then effect the final subtraction with the measured result from the measurement coil or detectors. Or, it would be possible to not have a compensation coil and only have a measurement coil or detector(s). Or, it would be possible to not have a measurement coil at all. Or, to have one or more of each in many combinations. Or, these coils could be combined with other magnetic detectors, such as hall effect or magnetoresistance detectors. For example, in the event that many different products were to be fabricated and tested, each with different electrical characteristics, a compensation coil could be constructed that would have nominally optimal properties for an average of over the FPDs to be tested and then smaller correction values could be added to the recovered signals in the electronic or computer software means provided after signal detection. These correction values can be obtained from signals measured from the additional measurement coils and/or magnetic detectors provided in the test. As these modifications would be apparent to one of ordinary skill in the art, it will be appreciated that these modifications are within the spirit of the present invention.

Although the invention has been described with reference to specific embodiments, this description is not meant to be construed in a limiting sense. Various modifications of the disclosed embodiments would be apparent to persons of ordinary skill in the art upon reference to the description of the invention. It is therefore contemplated that the appended claims will cover any modifications or embodiments as fall within the true scope of the invention.

1. A method in which an electrical signal is measured on an FPD that includes
the application of thermal or optical energy to the FPD under test
wherein said application of thermal or optical energy to the FPD is at a location on the FPD which varies in time relative the FPD
at least two electrical contacts to the FPD
at least one magnetic detector with a bandwidth greater than 10 Hz
at least one low noise preamplifier with a bandwidth greater than 10 Hz attached electrically to the FPD while the thermal or optical energy is applied
said preamplifier has an input referred noise voltage density level below 50 nV/sqrt(Hz) at at least one point in the frequency range from 100-10,000 Hz.
electronic or computer software means for collecting and analyzing said signals from the electrical contacts and said magnetic detector or detectors
said electronic or computer software means can process incoming signals with a bandwidth of greater than 10 Hz

2. A method as in claim 1 wherein said thermal or optical energy is a laser

3. A method as in claim 2 wherein said thermal or optical energy is substantially contained within an area less than 1 cmˆ2 on the FPD at any given instant in time.

4. A method as in claim 2 wherein said electronic or computer software means can receive incoming signals at least over the range 100 to 300 Hz.

5. A method as in claim 1 wherein at least one of the magnetic detectors constitutes a coil.

6. A method as in claim 5 wherein at least one of said magnetic coils has an area less than the active area of the FPD.

7. A method as in claim 6 wherein one of said magnetic coils has an area greater than 10% and less than 50% of the active area of the FPD.

8. A method as in claim 2 wherein said laser applies optical energy at any given instant predominantly to an area for which the shorter of the width and or the length is no greater than 5 times the pixel spacing on the FPD

9. A method as in claim 2 wherein said electronic or computer software means can receive incoming signals at least over the range 100 to 300 Hz and at least one of the magnetic detectors constitutes a coil.

10. A method as in claim 6 wherein one of said magnetic coils is connected in series with the electrical measurement on the panel.

11. A method as in claim 2 wherein number of electrical contacts to the FPD is less than one hundred

12. A method as in claim 2 wherein the laser applies optical energy to multiple and separated areas on the FPD simultaneously and the total area to which thermal energy is applied is less than 1 cmˆ2

13. A method as in claim 2 wherein more than one laser is used

14. A method as in claim 4 wherein at least one of the magnetic detectors is a hall effect device

15. A method as in claim 4 wherein at least one of the magnetic detectors is a magnetoresistive detector

16. A method as in claim 4 wherein at least one of the magnetic detectors is a SQUID detector

17. A method as in claim 2 in which the laser applies optical energy to at least one row or at least one column on the FPD

18. A method as in claim 2 in which the laser applies optical energy to a majority of the rows or a majority of the columns of the FPD

19. A method as in claim 4 wherein there is at least one coil wired in series with the FPD and at least one additional magnetic detector attached to electronic or computer software means.

20. A method as in claim 4 wherein said coil wired in series with the FPD is patterned on the FPD.

21. A method as in claim 4 wherein said coil is attached to the wafer chuck.

22. A method in which an electrical signal is measured on an FPD under test that includes
the application of optical energy to the FPD under test
wherein said application of thermal or optical energy to the FPD is at a location on the FPD which varies in time relative the FPD
at least two electrical contacts to the FPD all of which when taken together are electrically connected to each row and column of the FPD
at least one coil wired in series with the FPD with a number of turns times its area greater than 10 cmˆ2.
at least one low noise preamplifier with a bandwidth greater than 10 Hz attached electrically to the FPD while the thermal or optical energy is applied
said preamplifier has a noise voltage density level below 50 nV/sqrt(Hz) at at least one point in the frequency range from 100-10,000 Hz.
electronic or computer software means for collecting and analyzing said signals from the electrical contacts and said magnetic detector or detectors
said electronic or computer software means can process incoming signals with a bandwidth of greater than 10 Hz

23. A method as in claim 22 that includes an additional magnetic coil

24. A method as in claim 22 that includes a hall effect magnetic detector

25. A method as in claim 22 that includes a magnetoresistance detector

26. A method as in claim 18 in which the optical energy is applied to each of the rows and each of the columns

27. A method as in claim 22 in which the magnetic detector does not move relative to the FPD.

28. A method as in claim 4 in which the compensation coil has an area more than 2% of the active area of the FPD and less than 50%.
